(19) United States
(12) Patent Application Publication
(10) Pub. No.: US 2026/0131844 A1
(43) Pub. Date: May 14, 2026

(54) STEERING APPARATUS

(71) Applicant: Honda Motor Co., Ltd., Tokyo (JP)

(72) Inventor: Shotaro Odate, Tokyo (JP)

(21) Appl. No.: 19/378,488

(22) Filed: Nov. 4, 2025

(30) Foreign Application Priority Data
Nov. 8, 2024 (JP) 2024-195671

(51) Int. Cl. B62D 1/04; H03K 17/96

(52) U.S. Cl. CPC B62D 1/046; H03K 17/962

(57) ABSTRACT

A steering apparatus including a sensor portion of an electrostatic capacitance type including an electrode provided in a rim portion to detect a grip operation of the rim portion by the occupant. The rim portion extends along a closed curve and includes a skeleton portion forming a framework of the rim portion and a surface portion covering the rim portion over an entire circumference in the circumferential direction, a cut surface of the rim portion obtained by cutting the rim portion perpendicularly to the closed curve includes an inner-diameter-side region located on a side of the hub portion of the cut surface and an outer-diameter-side region located on an opposite side of the inner-diameter-side region of the cut surface, and the electrode is disposed between the skeleton portion and the surface portion and provided to extend in the inner-diameter-side region in the circumferential direction.

### CROSS-REFERENCE TO RELATED APPLICATION

This application is based upon and claims the benefit of priority from Japanese Patent Application No. 2024-195671 filed on Nov. 8, 2024, the content of which is incorporated herein by reference.

### BACKGROUND OF THE INVENTION

### Field of the Invention

This invention relates to a steering apparatus capable of detecting a grip state of a steering wheel.

### Description of the Related Art

In recent years, efforts to provide access to sustainable transportation systems that consider people in vulnerable positions among traffic participants have been intensifying. To achieve this, research and development on driving assistance technology is being conducted. Against this backdrop, a device is known that is equipped with a capacitive sensor on the rim of the steering wheel to detect the gripping state of the rim by the driver. Such a device is described, for example, in Japanese Examined Patent Publication No. 6674556 (JP6674556B).

In the device described in JP6674556B, a conductive part functioning as a contact sensor is provided over the entire circumference of the rim, and a blank part is provided in the lower circumferential portion of the rim where the conductive part is cut or notched to reduce contact sensitivity. This prevents the rim from being erroneously detected as being gripped when the occupant's abdomen or thigh contacts the rim.

However, even if a blank part is provided in the lower circumferential portion of the rim as the device described in JP6674556B, depending on the occupant's posture, the tilt operation of the steering wheel, and the rotational position of the steering wheel, the occupant's body may contact the rim outside the blank part, which may lead to erroneous detection of the rim being gripped.

### SUMMARY OF THE INVENTION

An aspect of the present invention is a steering apparatus for a vehicle including a hub portion coupled to a steering shaft, a rim portion extending along a closed curve having a predetermined shape over an entire circumference in a circumferential direction centered on the hub portion, and gripped by an occupant, a spoke portion connecting the hub portion with the rim portion, and a sensor portion of an electrostatic capacitance type including an electrode provided in the rim portion to detect a grip operation of the rim portion by the occupant. The rim portion includes a skeleton portion forming a framework of the rim portion and a surface portion covering the rim portion over an entire circumference in the circumferential direction, a cut surface of the rim portion obtained by cutting the rim portion perpendicularly to the closed curve includes an inner-diameter-side region located on a side of the hub portion of the cut surface and an outer-diameter-side region located on an opposite side of the inner-diameter-side region of the cut surface, and the electrode is disposed between the skeleton portion and the surface portion and provided to extend in the inner-diameter-side region in the circumferential direction.

### BRIEF DESCRIPTION OF THE DRAWINGS

The objects, features, and advantages of the present invention will become clearer from the following description of embodiments in relation to the attached drawings, in which:

FIG. 1 is a side view illustrating a schematic configuration near the driver's seat of a vehicle having a steering apparatus according to an embodiment of the present invention;

FIG. 2 is a view taken in the direction of arrow II in FIG. 1;

FIG. 3 is a cross-sectional view taken along line III-III in FIG. 2;

FIG. 4A is a front view of a rim portion of a steering wheel illustrating a grip operation of an occupant;

FIG. 4B is a cross-sectional view of main components of FIG. 4A;

FIG. 5 is a cross-sectional view of main components of the rim portion of FIG. 3;

FIG. 6A is a cross-sectional view of main components of a base member, illustrating an example in which a recess portion for positioning an electrode is provided on a surface of the base member of the rim portion;

FIG. 6B is a cross-sectional view of main components of the rim portion, illustrating an example in which a recess portion for positioning an electrode is provided on a surface of the base member of the rim portion;

FIG. 7 is a block diagram illustrating a control configuration of the steering apparatus according to the embodiment of the present embodiment;

FIG. 8 is a flowchart illustrating an example of processing performed by the controller in FIG. 7;

FIG. 9 is a view schematically illustrating a positional relationship between the steering wheel and an occupant’s lower limb portion; and

FIG. 10 is a front view illustrating a modification of the rim portion.

### DETAILED DESCRIPTION OF THE INVENTION

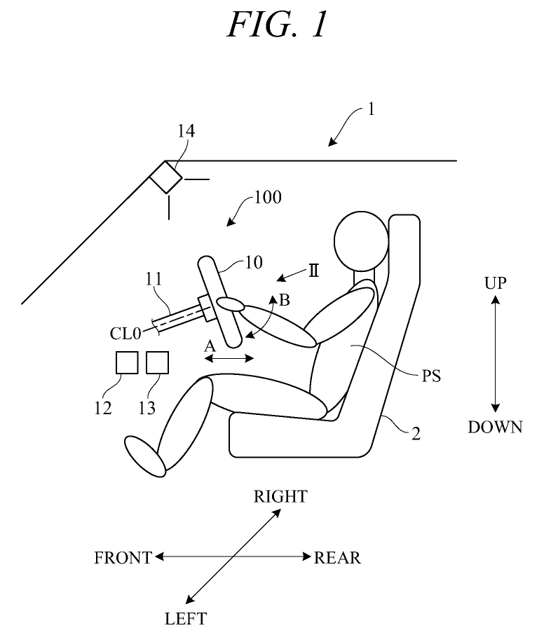

Hereinafter, an embodiment of the present invention will be described with reference to FIGS. 1 to 10. The steering apparatus according to an embodiment of the present invention is mounted on a vehicle. The vehicle is, for example, a self-driving vehicle having a self-driving capability that does not require driving operation by a driver. The vehicle may also be a manually operated vehicle that requires driving operation by a driver. Below, an example where the steering apparatus is applied to a self-driving vehicle will be described. This self-driving vehicle is configured to switch a drive mode from a self-drive mode, which does not require driving operation by a driver, to a manual drive mode, which requires driving operation by a driver.

FIG. 1 is a side view illustrating a schematic configuration near the driver's seat of a vehicle 1 having a steering apparatus 100 according to an embodiment of the present invention. Below, the front-rear direction, left-right direction, and up-down direction are defined as illustrated in FIG. 1, and the configuration of each part will be described according to this definition. The front-rear direction, left-right direction, and up-down direction correspond to the front-rear direction (length direction), left-right direction (width direction), and up-down direction (height direction) of the vehicle 1.

FIG. 1 illustrates a state where an occupant PS is seated in the driver's seat 2 of the vehicle 1. As illustrated in FIG. 1, the steering apparatus 100 includes a steering wheel 10 arranged facing the driver's seat 2 and operated by the occupant PS. The steering wheel 10 is supported at a distal end (a rear end) of a steering shaft 11 that extends with an upward slope along a centerline CL0 from the front to the rear of the vehicle. The steering shaft 11 rotates integrally with the steering wheel 10 in response to the operation of the steering wheel 10.

Although detailed illustration is omitted, the steering apparatus 100 includes a telescopic mechanism 12 and a tilt mechanism 13. The steering wheel 10 is movable in the front-rear direction (direction of arrow “A” in FIG. 1) by the telescopic mechanism 12 and movable in the up-down direction by the tilt mechanism 13. This allows the occupant PS to move the steering wheel 10 to any position. The telescopic mechanism 12 and the tilt mechanism 13 are driven by manual operation of the occupant. At least one of the telescopic mechanism 12 and the tilt mechanism 13 may be driven by an actuator (e.g., an electric motor).

Inside the vehicle cabin, a camera 14 with an imaging element such as a CCD or CMOS is installed, for example, above the front windshield. The camera 14 images the occupant PS and can recognize the physique and posture of the occupant PS based on the image signal acquired by the camera 14.

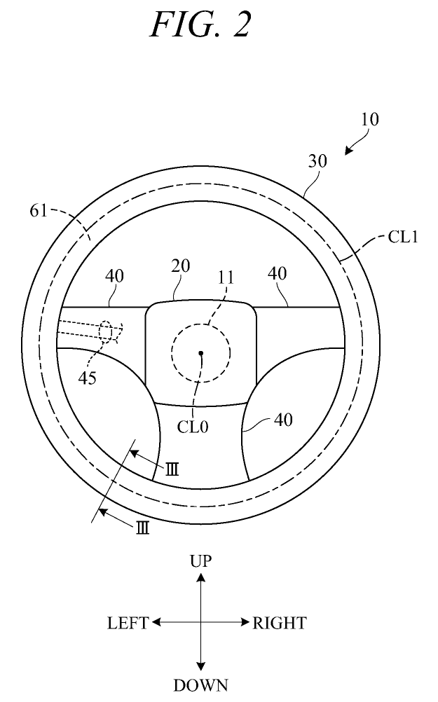

FIG. 2 is a front view of the steering wheel 10 (view taken in the direction of arrow II in FIG. 1). As illustrated in FIG. 2, the steering wheel 10 includes a hub portion 20 coupled to the steering shaft 11, a substantially annular rim portion 30 arranged around the hub portion 20, and a spoke portion 40 connecting the hub portion 20 with the rim portion 30. The centerline CL0 passes through the central part of the hub portion 20 (e.g., the center of the hub portion 20), and the steering wheel 10 extends along a plane perpendicular to the centerline CL0. Below, the direction along a circle centered on the centerline CL0 is defined as a circumferential direction, and the direction extending radially from the centerline CL0 is defined as a radial direction.

The rim portion 30 extends along a circular or substantially circular reference line CL1 centered on the centerline CL0. The rim portion 30 is not limited to a circular or substantially circular shape and may be rectangular or substantially rectangular. The rim portion 30 is gripped by the occupant PS, and the steering wheel 10 is operated via the rim portion 30. The spoke portion 40 consists of three spokes extending leftward, rightward, and downward from the hub portion 20. The number of spokes in the spoke portion 40 may be two or four, and the configuration of the spoke portion 40 is not limited to the configuration illustrated in FIG. 2.

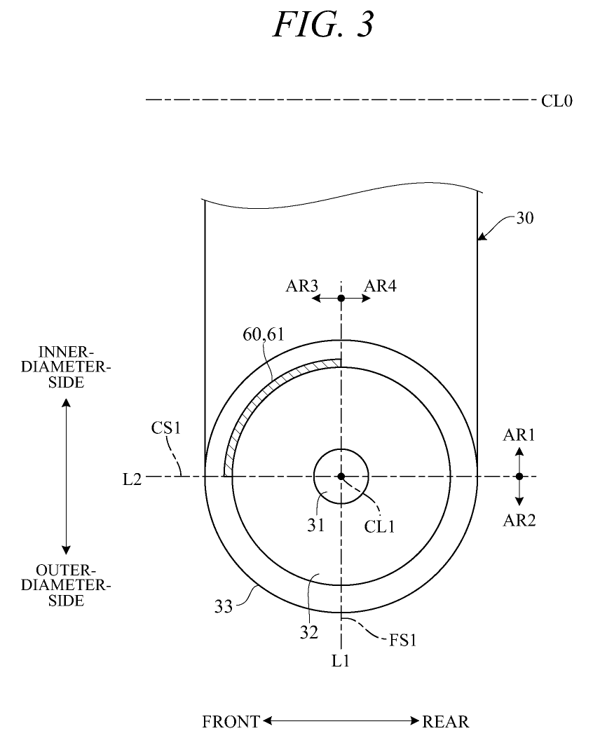

The rim portion 30 has the same cross-sectional shape throughout its entire circumference. FIG. 3 is a cross-sectional view of the rim portion 30 cut perpendicular to the reference line CL1 (cross-sectional view taken along line III-III in FIG. 2). The reference line CL1 is located at the center of the cross-section of the rim portion 30. FIG. 3 illustrates a straight line L1 extending along a plane FS1 perpendicular to the centerline CL0 passing through the reference line CL1, and a straight line L2 parallel to the centerline CL0 (perpendicular to the straight line L1) passing through the reference line CL1. The straight line L2 extends in the front-rear direction, more specifically with a downward slope toward the front, and extends along a substantially cylindrical curved surface CS1 centered on the centerline CL0.

As illustrated in FIG. 3, the rim portion 30 includes a core metal 31, a base member 32, and a surface layer 33. The core metal 31 is provided at the central part of the rim portion 30. The core metal 31 is formed of a highly rigid metal material such as stainless steel. The core metal 31 extends along the reference line CL1 and constitutes a skeletal portion forming the framework of the rim portion 30. In FIG. 3, the core metal 31 is illustrated as having a substantially circular cross-section, but the core metal 31 may be in a pipe shape (substantially cylindrical shape) or a shape bent into a substantially C-shape or U-shape.

The base member 32 has a substantially cylindrical cross-section. The base member 32 is formed to enclose the entire outer peripheral surface of the core metal 31 and defines the overall shape of the rim portion 30. The base member 32 is formed of a material with lower rigidity than the core metal 31 (e.g., a resin material such as non-conductive polyurethane) and constitutes a base portion of the rim portion 30. The surface layer 33 covers the entire outer peripheral surface of the base member 32, and the surface of the surface layer 33 is exposed to the outside. That is, the surface layer 33 constitutes a surface portion that covers the entire circumference of the rim portion 30 in the circumferential direction. When the occupant grips the rim portion 30, the occupant's hand contacts the surface layer 33. The surface layer 33 is made of resin material, leather, wood, etc.

In FIG. 3, the region radially inside the curved surface CS1 (straight line L2), i.e., the region on the centerline CL0 side, is called an inner-diameter-side region AR1, and the region radially outside the curved surface CS1, i.e., the region on the opposite side of the centerline CL0, is called an outer-diameter-side region AR2. Also, the region in front of the plane FS1 (straight line L1) is called a front-side region AR3, and the region behind the plane FS1 (occupant side) is called a rear-side region AR4. The front-side region AR3 is the region on the proximal end side of the steering shaft 11, and the rear-side region AR4 is the region on the distal end side of the steering shaft 11.

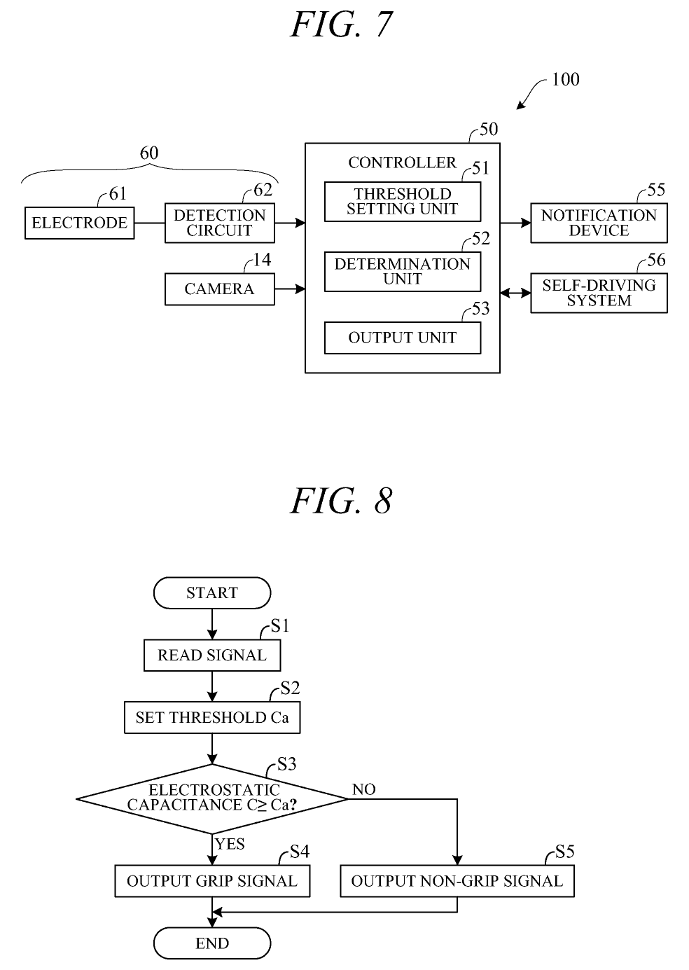

The steering apparatus 100 according to the present embodiment further includes a sensor unit 60 of electrostatic capacitance type for detecting a grip operation of the occupant gripping the rim portion 30. The sensor unit 60 includes: a power supply (not illustrated); an electrode 61, which is provided in the rim portion 30; and a detection circuit 62 (FIG. 7), which detects electrostatic capacitance of the electrode 61 or a change in the electrostatic capacitance. The detection circuit 62 detects, for example, an electric characteristic of the electrode 61, that is, the magnitude of electrostatic capacitance between the electrode 61 and the ground (the vehicle body). The electrostatic capacitance detected by the detection circuit 62 increases as a detection target (the occupant’s body) approaches the electrode 61, and decreases as the detection target moves away from the electrode.

As illustrated in FIG. 3, the electrode 61 is interposed between the base member 32 and the surface layer 33, and is interposed in the entire region of an inner-diameter-side region AR1 and a front-side region AR3 of the rim portion 30. In other words, the electrode 61 is disposed on the opposite side of a portion facing the occupant’s lower limbs and on the opposite side of a portion facing the occupant’s abdomen. The electrode 61 is disposed along an outer circumferential surface of the base member 32, and has a quarter circle shape as a whole. As indicated by dotted lines in FIG. 2, one ends of a pair of signal lines 45 are connected with the electrode 61. The signal lines 45 are routed inside the spoke portion 40 along the spoke portion 40, and the other ends of them are connected with the detection circuit 62.

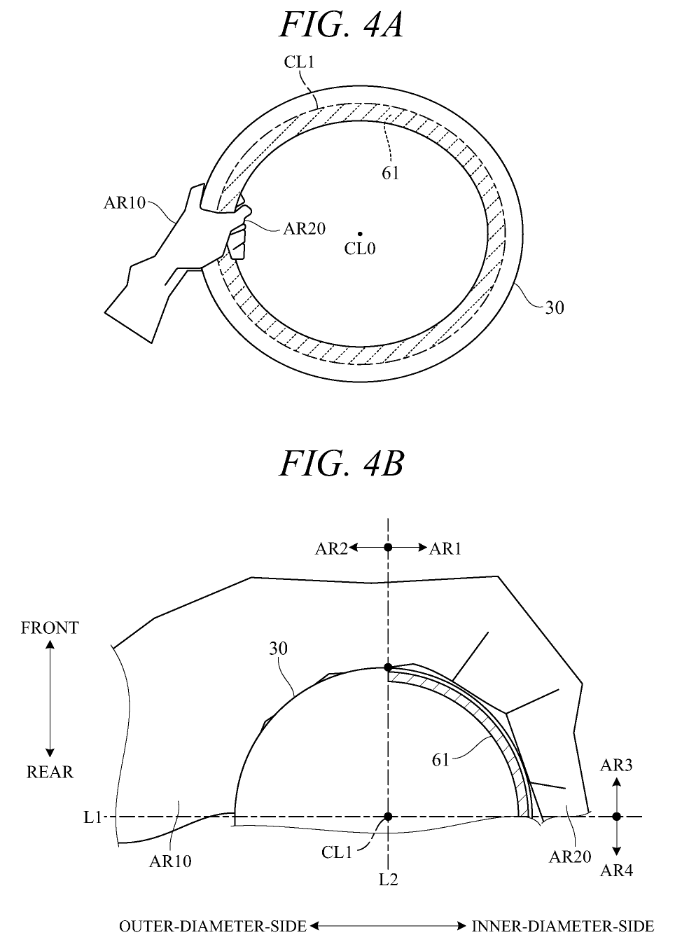

FIG. 4A is a front view (when viewed from the occupant, that is, from the rear) of the rim portion 30, and illustrates the grip operation of the occupant, and FIG. 4B is a cross-sectional view of the main components of FIG. 4A. In FIG. 4A, for convenience, illustration of the hub portion 20 and the spoke portion 40 of the steering wheel 10 is omitted.

As illustrated in FIGS. 4A and 4B, when the occupant grips the rim portion 30, a range between a CM joint and an MP joint of the occupant’s palm and the thenar eminence (referred to as a wrist-side region AR10) are mainly located in an outer-diameter-side region AR2 of the rim portion 30. On the other hand, a range between the bases of fingers and fingertips (referred to as a finger-side region AR20) is mainly located in the inner-diameter-side region AR1. In this situation, the finger-side region AR20 comes close to the electrode 61. The electrostatic capacitance of the electrode 61 increases accordingly, and it becomes possible to detect the grip operation of the occupant gripping the steering wheel 10.

In particular, the electrode 61 is disposed in the inner-diameter-side region AR1 of the rim portion 30. The inner-diameter-side region AR1 of the rim portion 30 faces the finger-side region AR20 of the occupant’s hand, so that the occupant gripping the steering wheel 10 (the rim portion 30) can be detected with accuracy. In other words, no electrode 61 is present in the outer-diameter-side region AR2. Therefore, even though the occupant’s lower limb or the like comes into contact with the rim portion 30, it is possible to prevent the sensor unit 60 from erroneously detecting the contact.

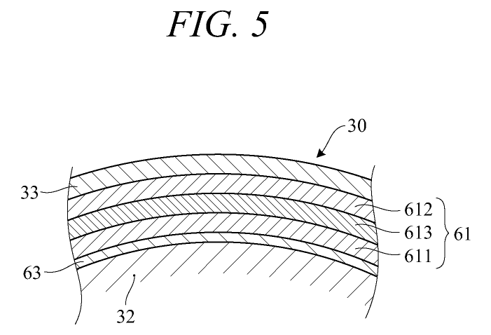

FIG. 5 is a cross-sectional view of the main components of the rim portion 30 of FIG. 3, and illustrates the configuration of the electrode 61 in more detail. As illustrated in FIG. 5, the electrode 61 includes: a pair of electrode layers (an inner electrode layer 611 and an outer electrode layer 612) each having a substantially thin plate shape; and an insulation layer 613, which is interposed between the pair of electrode layers 611 and 612.

An adhesive (an adhesive portion) 63 is applied to the outer circumferential surface of the base member 32, and an adhesive layer is formed. The inner electrode layer 611 adheres to the outer circumferential surface of the base member 32 via the adhesive 63 over the entire circumference of the rim portion 30 in the inner-diameter-side region AR1 and in the front-side region AR3 in FIG. 3. The outer electrode layer 612 is disposed to face the inner circumferential surface of the surface layer 33 so as to be opposite to the inner electrode layer 611 over the entire region of the inner electrode layer 611 via the insulation layer 613.

In the present embodiment, the electrode 61 is provided only in a partial region (the inner-diameter-side region AR1 and the front-side region AR3) of the circle centered around a reference line CL1 (FIG. 3). Thus, the area of the electrode 61 is smaller than that in a case where the electrode 61 is provided over the entire circumference of the circle centered around the reference line CL1. For this reason, the detection sensitivity of the sensor unit 60 tends to decrease, but the electrode 61 is configured with the insulation layer 613 interposed between the pair of electrode layers 611 and 612, so that a decrease in the detection sensitivity of the sensor unit 60 can be suppressed.

In the present embodiment, the electrode 61 is attached to the surface of the base member 32 in an overlapping manner. Thus, the electrode 61 can be easily attached as compared with a case where the electrode 61 is provided inside the rim portion 30 by insert molding, so that the manufacturing cost of the steering wheel 10 including the electrode 61 can be suppressed. In addition, the signal lines 45 (FIG. 2), which are connected with the electrode 61, are routed along the spoke portion 40. Thus, it becomes possible to easily route the signal lines 45 as compared with the case where the electrode 61 is provided inside the rim portion 30 by insert molding.

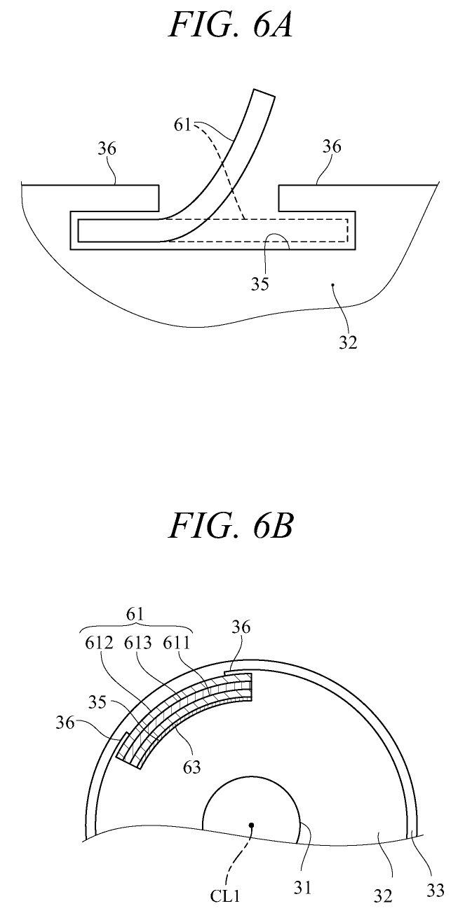

As described above, the electrode 61 adheres to and is fixed to the outer circumferential surface of the base member 32. However, in this form, when the temperature of the external environment changes and the base member 32 expands and compresses, the position misalignment of the electrode 61 may occur. Therefore, a engaging portion having a recess shape for restricting the position of the electrode 61 may be provided to prevent the position misalignment of the electrode 61. FIG. 6A is a view schematically illustrating its example.

As illustrated in FIG. 6A, a recess portion 35 having a depth corresponding to the thickness of the electrode 61, and engaging portions 36, which protrude in the circumferential direction to respectively cover both circumferential end portions of the recess portion 35, are provided on the outer circumferential surface of the base member 32. In disposing the electrode 61 in the recess portions 35, first, while the electrode 61 is being bent, one end portion of the electrode 61 is inserted into the engaging portion 36 on one end in the circumferential direction of the recess portion 35. Next, while the central portion of the electrode 61 is being bent in a convex shape toward the opposite side of the recess portion 35, the other end portion of the electrode 61 is inserted into the engaging portion 36 on the other end in the circumferential direction of the recess portion 35. This enables the entirety of the electrode 61 to be disposed in the recess portion 35, as indicated by a dotted line in FIG. 6A.

FIG. 6B is a cross-sectional view illustrating the arrangement of the electrode 61 of FIG. 6A in more detail. As illustrated in FIG. 6B, the electrode 61 (the inner electrode layer 611, the insulation layer 613, and the outer electrode layer 612) is disposed in the recess portion 35 via the adhesive 63. In a state in which the electrode 61 is disposed in the recess portion 35, both end portions in the circumferential direction of the electrode 61 are respectively covered with the engaging portions 36. Accordingly, the position of the electrode 61 is restricted, so that the position misalignment of the electrode 61 can be prevented. After the electrode 61 is disposed in the recess portion 35, the electrode 61 and the engaging portions 36 are covered with the surface layer 33.

FIG. 7 is a block diagram illustrating a control configuration of the steering apparatus 100 according to the present embodiment. As illustrated in FIG. 7, the steering apparatus 100 includes the sensor unit 60, a camera 14, a controller 50, a notification device 55, and a self-driving system 56. The notification device 55 is a device for notifying the occupant of a grip request for gripping the steering wheel 10, and includes a speaker and a monitor.

Signals from the detection circuit 62 and the camera 14 are input into the controller 50. The controller 50 includes a computer as a processing device including a CPU, a ROM, a RAM, and other peripheral circuits. The controller 50 functions as a threshold setting unit 51, a determination unit 52, and an output unit 53.

The threshold setting unit 51 recognizes the physique and posture of the occupant, based on an image signal acquired by the camera 14. Then, a threshold Ca for the grip determination of gripping the steering wheel 10 is set, based on the physique and posture that have been recognized. The threshold setting unit 51 calculates the shortest distance between the occupant’s lower limb or abdomen and the steering wheel 10, based on the occupant's physique and posture that have been recognized, and sets the threshold Ca to a larger value as the distance is shorter. That is, the threshold Ca increases, as the lower limb comes closer to the steering wheel 10.

The determination unit 52 determines whether the electrostatic capacitance C, which has been detected through the detection circuit 62, is equal to or larger than the threshold Ca, which is set by the threshold setting unit 51. Then, in a case where the electrostatic capacitance C is equal to or greater than the threshold Ca (C ≥ Ca), the determination unit 52 determines that the steering wheel 10 is gripped. On the other hand, in a case where the electrostatic capacitance C is smaller than the threshold Ca (C < Ca), the determination unit 52 determines that the steering wheel 10 is not gripped.

The output unit 53 outputs a determination result by the determination unit 52 to the notification device 55 and the self-driving system 56. In addition to this, the output unit 53 communicates with the self-driving system 56, and determines whether a grip request for gripping the steering wheel 10 is output from the self-driving system 56. When the grip request is output from the self-driving system 56, a signal is output to the notification device 55 to notify the occupant that the occupant should grip the steering wheel 10.

For example, while the vehicle 1 is traveling in the self-drive mode, the self-driving system 56 determines whether it becomes necessary to switch the drive mode from the self-drive mode to the manual drive mode, based on a situation in the surroundings of the vehicle 1 and a situation of the vehicle itself. Then, when determining that it is necessary to switch from the self-drive mode to the manual drive mode (for example, when the self-drive level is changed from level 3 to level 2), the self-driving system 56 outputs the grip request for gripping the steering wheel 10.

FIG. 8 is a flowchart illustrating an example of processing performed by the CPU of the controller 50 in accordance with a program stored beforehand. The processing illustrated in this flowchart is started on condition that the grip request for gripping the steering wheel 10 is output from the self-driving system 56 while the vehicle 1 is traveling in the self-drive mode, that is, when the grip request for gripping the steering wheel 10 is notified from the notification device 55, and is repeated at a predetermined cycle. The processing illustrated in the flowchart may be started when the power switch of the vehicle 1 is turned on regardless of the presence or absence of the output of the grip request.

First, in S1 (S: processing step), the CPU of the controller 50 reads signals from the sensor unit 60 (the detection circuit 62) and the camera 14. Next, in S2, the CPU recognizes the occupant’s physique and posture, based on an image signal from the camera 14, and sets the threshold Ca in accordance with the occupant’s physique and posture. Specifically, the CPU calculates the shortest distance between the occupant’s lower limb or abdomen and the steering wheel 10, based on the occupant's physique and posture that have been recognized, and sets the threshold Ca to a larger value as the distance is shorter. Next, in S3, the CPU determines whether the electrostatic capacitance C, which has been detected by the sensor unit 60, is equal to or greater than the threshold Ca.

In a case where an affirmative determination is made in S3, the processing proceeds to S4, and in a case where a negative determination is made in S3, the processing proceeds to S5. In S4, the CPU outputs a grip signal indicating that the steering wheel 10 is gripped to the notification device 55 and the self-driving system 56. Thus, the notification of the grip request for gripping the steering wheel 10 is stopped.

On the other hand, in S5, a non-grip signal indicating that the steering wheel 10 is not gripped is output to the notification device 55 and the self-driving system 56. While the non-grip signal is being output, the notification device 55 continuously notifies the grip request. In a case where the grip signal is not output even though the notification device 55 has notified the grip request for a predetermined period of time, that is, when the occupant does not grip the steering wheel 10, the self-driving system 56 performs a predetermined operation (for example, a stop operation) of the vehicle 1.

The operation of the steering apparatus 100 according to the present embodiment is summarized as follows. While traveling in the self-drive mode, when it becomes necessary to switch the drive mode to the manual drive mode, the notification device 55 notifies the grip request for gripping the steering wheel 10. Thus, the occupant (the driver) grips the steering wheel 10. When the steering wheel 10 is gripped, the electrostatic capacitance C, which has been detected by the sensor unit 60, increases, and the electrostatic capacitance C becomes equal to or greater than the threshold Ca. As a result, the grip signal is output to the self-driving system 56, and the drive mode is switched to the manual drive mode (S4).

In this case, the electrode 61 of the sensor unit 60 is provided in the inner-diameter-side region AR1 and in the front-side region AR3 of the rim portion 30 (FIG. 3). Therefore, when the occupant grips the rim portion 30, the finger-side region AR20 (FIG. 4A) comes close to the electrode 61, and the electrostatic capacitance C, which is detected by the sensor unit 60, increases. This enables the grip operation of gripping the steering wheel 10 to be satisfactorily detected.

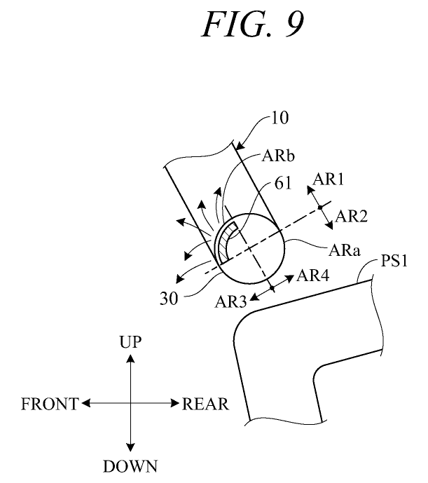

FIG. 9 is a view schematically illustrating a positional relationship between the steering wheel 10 and an occupant’s lower limb portion PS1 (the circumference of a thigh). As illustrated in FIG. 9, the occupant’s lower limb portion PS1 comes closest to a region ARa, which is located in the outer-diameter-side region AR2 and in a rear-side region AR4 in a lower part of the steering wheel 10. In the present embodiment, the electrode 61 is not provided in such a region ARa, but the electrode 61 is provided in a region ARb, which is located in the inner-diameter-side region AR1 and in the front-side region AR3, and which is farthest from the lower limb portion PS1. For this reason, the occupant is not present in the directions of the lines of electric force of the electrode 61 as indicated by arrows. It becomes possible to prevent erroneous detection of the grip on the steering wheel 10, when a portion other than the palm of the occupant’s hand comes close to the steering wheel 10.

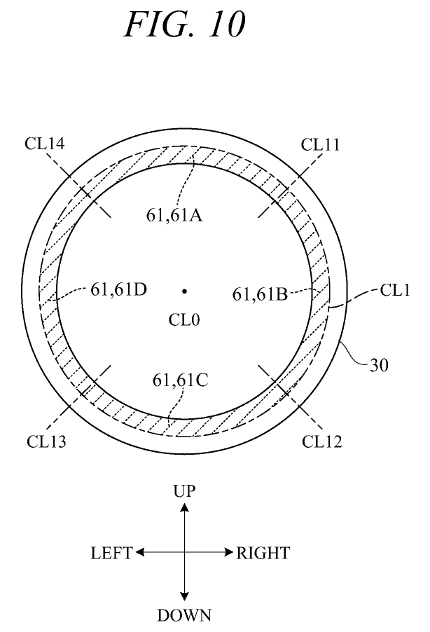

In the above description, the single electrode 61 is provided over the entire circumference of the rim portion 30, but a plurality of electrodes 61 may be provided in the circumferential direction. FIG. 10 is a front view (when viewed from the rear) of the rim portion 30, and illustrates its example. As illustrated in FIG. 10, the electrode 61 is divided into four equal parts by axes CL11, CL12, CL13, and CL14, which extend radially outward from a centerline CL0. Therefore, four electrodes 61A, 61B, 61C, and 61D (dotted lines) in the circumferential direction are provided in the inner-diameter-side region AR1 and in the front-side region AR3 (FIG. 3) of the rim portion 30.

A detection circuit 62 (FIG. 7) is individually connected with each of the electrodes 61A to 61D, and the steering apparatus 100 in FIG. 10 includes four sensor units 60. This enables the CPU to determine whether the steering wheel 10 is gripped, and in addition, which region in the circumferential direction of the steering wheel 10 is gripped. In FIG. 10, the electrode 61 is divided into four parts in the circumferential direction, but may be divided into two, three, or five or more to provide a plurality of electrodes 61 in the circumferential direction. In a case where the electrode 61 is provided to be divided into a plurality of parts in the circumferential direction, the electrodes may not be necessarily divided equally in the circumferential direction.

According to the present embodiment, the following functions and effects are achievable.

(1) The steering apparatus 100 for the vehicle includes: the hub portion 20, which is coupled to the steering shaft 11; the rim portion 30, which extends around the hub portion 20 along the reference line CL1 having a substantially circular shape in the circumferential direction over the entire circumference centered on the hub portion 20, and which is gripped by an occupant; and the spoke portion 40, which connects the hub portion 20 with the rim portion 30 (FIGS. 1 and 2). The steering apparatus 100 further includes the sensor unit 60 of electrostatic capacitance type, the sensor unit 60 including the electrode 61, which is provided in the rim portion 30 to detect a grip operation of the occupant gripping the rim portion 30 (FIG. 7). The rim portion 30 includes: the core metal 31, which forms the framework of the rim portion 30; and the surface layer 33, which covers the entire circumference of the rim portion 30 in the circumferential direction (FIG. 3). In a cut section of the rim portion 30 obtained by cutting the rim portion 30 perpendicularly to the reference line CL1, in a case where a region on the hub portion 20 side is defined as the inner-diameter-side region AR1 and a region on the opposite side of the inner-diameter-side region AR1 is defined as the outer-diameter-side region AR2, the electrode 61 is disposed between the core metal 31 and the surface layer 33, and extends in the inner-diameter-side region AR1 over the circumferential direction (FIGS. 3 and 4A).

By providing the electrode 61 in the inner-diameter-side region AR1 of the rim portion 30 in this manner, it becomes possible to prevent erroneous detection that the steering wheel 10 is gripped by the occupant when the occupant’s lower limb portion comes into contact with the steering wheel 10. Since the electrode 61 is provided over the entire circumference of the rim portion 30, there is no need for providing a blank portion in which no electrode 61 is provided in a part in the circumferential direction of the steering wheel 10. Therefore, the configuration of the steering wheel 10 is facilitated. In any area in the circumferential direction of the steering wheel 10, the electrode 61 is located in the inner-diameter-side region AR1 of the rim portion 30, so that the gripping state of gripping the steering wheel 10 can be detected with accuracy regardless of the occupant’s posture, the tilt operation of the steering wheel 10, the rotation position of the steering wheel 10, or the like.

(2) The electrode 61 extends in the circumferential direction in the front-side region AR3 of the vehicle 1. The front-side region AR3 is the proximal end side of the steering shaft 11 in the inner-diameter-side region AR1 of the cut section of the rim portion 30 (FIGS. 3 and 4A). In this manner, the electrode 61 is provided in the front-side region AR3, which is farthest from the occupant in the inner-diameter-side region AR1 of the rim portion 30, so that erroneous detection of the grip operation can be satisfactorily prevented when an area other than the occupant’s palm comes into contact with the steering wheel 10.

(3) The rim portion 30 further includes the base member 32, which surrounds the core metal 31 over the entire circumference (FIG. 2). The electrode 61 includes: the inner electrode layer 611, which is attached to the surface of the base member 32; the outer electrode layer 612, which is disposed to face the surface layer 33 and is opposite to the inner electrode layer 611; and the insulation layer 613, which is interposed between the inner electrode layer 611 and the outer electrode layer 612 (FIG. 5). This enables the electrode 61 to be easily provided in the rim portion 30 as compared with a case where the electrode 61 is incorporated in the rim portion 30 by insert molding.

(4) The steering apparatus 100 further includes the adhesive 63, which is provided on the surface of the base member 32, and which adheres to the inner electrode layer 611 (FIG. 5). This facilitates an attaching step of the electrode 61, so that the manufacturing cost of the steering apparatus 100 can be suppressed.

(5) The base member 32 includes the engaging portion 36, which has a recess shape, and which retains an end portion in the circumferential direction of the electrode 61 (FIGS. 6A and 6B). Accordingly, it becomes possible to prevent position misalignment of the electrode 61 when the temperature of the external environment changes and the base member 32 expands and compresses.

(6) The sensor unit 60 further includes the signal line 45 having one end electrically connected with the electrode 61 and extending along the spoke portion 40 (FIG. 2). This facilitates routing of the signal line 45.

(7) The steering apparatus 100 further includes: the camera 14, which detects the occupant’s physique and posture; the determination unit 52, which determines whether the rim portion 30 is gripped in accordance with the magnitude of the electrostatic capacitance detected through the electrode 61 relative to the threshold Ca; and the threshold setting unit 51, which sets the threshold Ca in accordance with the occupant’s physique and posture detected by the camera 14 (FIGS. 1 and 7). Accordingly, it becomes possible to accurately determine whether the steering wheel 10 is gripped regardless of the occupant’s physique or posture.

(8) The electrode 61 may include the plurality of electrodes 61 (61A, 61B, 61C, and 61D), which are divided in the circumferential direction, and which are disposed in the rim portion 30 (FIG. 10). In this case, the controller 50 further has a function as the grip region identification unit that identifies the grip region of the occupant gripping the rim portion 30 in accordance with signals from the plurality of electrodes 61. According to this configuration, it becomes possible to identify which region in the circumferential direction of the steering wheel 10 the occupant is gripping.

The above embodiments can be modified into various forms. Hereinafter, some modifications will be described. In the above embodiment, the electrode 61 is provided in the inner-diameter-side region AR1 and the front-side region AR3 of the rim portion 30 over the entire circumference of the rim portion 30 centered on the centerline CL0. However, as long as it is provided in the inner-diameter-side region AR1 of the rim portion 30, part or all of the electrode 61 may be provided in the rear-side region AR4. The electrode 61 may be provided in part of the circumferential direction centered on the centerline CL0. In the above embodiment, the electrode 61 is provided in a quarter-circle area of the cross-section of the rim portion 30 centered on the reference line CL1. However, as long as it is provided in at least the inner-diameter-side region AR1, the electrode 61 may be provided in a narrower or wider area than the quarter-circle.

In the above embodiment, the rim portion 30 is made to extend over the entire circumference centered on the hub portion 20 along the reference line CL1, which is a substantially circular closed curve, but the overall shape of the rim portion 30, i.e., the shape of the closed curve (a predetermined shape), is not limited to a circle. For example, the rim portion 30 may be entirely elliptical or substantially rectangular. In the above embodiment, the electrode 61 is configured by the inner electrode layer 611 (a first electrode layer) and the outer electrode layer 612 (a second electrode layer) facing each other via the insulation layer 613, but the configuration of the electrode is not limited to the configuration described above. In the above embodiment, the inner electrode layer 611 is adhered to the surface of the base member 32 via the adhesive 63, but the electrode 61 may be provided on the rim portion 30 by other methods. In the above embodiment, the signal line 45 connected to the electrode 61 is made to extend along the spoke portion 40, but a wire member extending along the spoke portion is not limited to the signal line.

In the above embodiment, the physique and posture of the occupant are detected by the camera 14, but the configuration of a detection part is not limited to the configuration described above. The detection part may be configured to detect the physique or posture of the occupant. For example, a single or multiple seat occupancy sensor may be provided on the seating surface of the seat cushion and/or seat back, and the physique or posture of the occupant may be detected based on signals from the seat occupancy sensor. Therefore, the threshold setting unit 51 may set the threshold Ca according to the physique or posture of the occupant. When the position of the steering wheel 10 is adjusted by the telescopic mechanism 12 and the tilt mechanism 13, the positional relationship between the occupant and the steering wheel 10 may remain constant regardless of the physique of the occupant. Therefore, a detection part (e.g., camera 14) may detect the degree of proximity between the steering wheel 10 and the body of the occupant PS (e.g., a lower limb), and the threshold setting unit 51 may set the threshold Ca based on the detection results.

The above embodiment can be combined as desired with one or more of the above modifications. The modifications can also be combined with one another.

According to the present invention, it is possible to accurately detect a gripping state of a steering wheel.

Above, while the present invention has been described with reference to the preferred embodiments thereof, it will be understood, by those skilled in the art, that various changes and modifications may be made thereto without departing from the scope of the appended claims.

What is claimed is:

1. A steering apparatus for a vehicle comprising
a hub portion coupled to a steering shaft;
a rim portion extending along a closed curve having a predetermined shape over an entire circumference in a circumferential direction centered on the hub portion, and gripped by an occupant;
a spoke portion connecting the hub portion with the rim portion; and
a sensor portion of an electrostatic capacitance type including an electrode provided in the rim portion to detect a grip operation of the rim portion by the occupant, wherein
the rim portion includes a skeleton portion forming a framework of the rim portion and a surface portion covering the rim portion over an entire circumference in the circumferential direction,
a cut surface of the rim portion obtained by cutting the rim portion perpendicularly to the closed curve includes an inner-diameter-side region located on a side of the hub portion of the cut surface and an outer-diameter-side region located on an opposite side of the inner-diameter-side region of the cut surface, and
the electrode is disposed between the skeleton portion and the surface portion and provided to extend in the inner-diameter-side region in the circumferential direction.

2. The steering apparatus according to claim 1, wherein
the electrode is provided to extend in the circumferential direction in a region on a proximal end side of the steering shaft within the inner-diameter-side region of the cut surface of the rim portion.

3. The steering apparatus according to claim 1, wherein
the rim portion further includes a base portion surrounding the skeleton portion over an entire circumference, and
the electrode includes a first electrode layer attached to a surface of the base portion, a second electrode layer disposed opposite the first electrode layer so as to face the surface portion, and an insulation layer interposed between the first electrode layer and the second electrode layer.

4. The steering apparatus according to claim 3, further comprising
an adhesive portion provided on the surface of the base portion to adhere the first electrode layer.

5. The steering apparatus according to claim 3, wherein
the base portion includes an engaging portion formed in a concave shape to retain an end of the electrode in the circumferential direction.

6. The steering apparatus according to claim 1, wherein
the sensor portion further includes a wire member having one end electrically connected with the electrode and extending along the spoke portion.

7. The steering apparatus according to claim 1, further comprising
a detection part configured to detect at least one of an occupant’s physique and posture; and
an electronic control unit having a microprocessor and a memory connected to the microprocessor, wherein
the microprocessor is configured to perform
determining whether the rim portion is gripped in accordance with a magnitude of an electrostatic capacitance detected by the detection part relative to a threshold, and
setting the threshold in accordance with the at least one of the occupant’s physique and posture.

8. The steering apparatus according to claim 7, wherein
the microprocessor is configured to perform
the determining including calculating a shortest distance from a lower limb of the occupant to the rim portion in accordance with the at least one of the occupant’s physique and posture detected by the detection part, and setting the threshold higher as the shortest distance decreases.

9. The steering apparatus according to claim 1, further comprising
an electronic control unit having a microprocessor and a memory connected to the microprocessor, wherein
the electrode includes a plurality of electrodes divided in the circumferential direction and arranged in the rim portion, and
the microprocessor is configured to perform
identifying a grip region of the rim portion by the occupant in accordance with signals from the plurality of electrodes.
